(19) United States
(12) Patent Application Publication
(10) Pub. No.: US 2014/0273436 A1
(43) Pub. Date: Sep. 18, 2014

(54) METHODS OF FORMING BARRIER LAYERS FOR CONDUCTIVE COPPER STRUCTURES

(71) Applicant: GLOBALFOUNDRIES INC., Grand Cayman (KY)

(72) Inventors: Bernd Hintze, Langebrueck (DE); Frank Koschinsky, Radebeul (DE)

(73) Assignee: GLOBALFOUNDRIES Inc., Grand Cayman (KY)

(21) Appl. No.: 13/834,292

(22) Filed: Mar. 15, 2013

(51) Int. Cl. H01L 21/768

(52) U.S. Cl. CPC H01L 21/76856; H01L 21/76843
USPC 438/653

(57) ABSTRACT

One illustrative method disclosed herein includes forming a trench/via in a layer of insulating material, forming a barrier layer in at least the trench/via, after forming said barrier layer, performing at least one process operation to introduce manganese into the barrier layer and thereby define a manganese-containing barrier layer, forming a substantially pure copper-based seed layer above the manganese-containing barrier layer, depositing a bulk copper-based material above the copper-based seed layer so as to overfill the trench/via, and removing excess materials positioned outside of the trench/via to thereby define a copper-based conductive structure.

### BACKGROUND OF THE INVENTION

1. Field of the Invention

Generally, the present disclosure relates to the manufacture of sophisticated semiconductor devices, and, more specifically, to various methods of forming barrier layers for copper-based conductive structures, such as conductive lines/vias, that are formed on integrated circuit products.

2. Description of the Related Art

The fabrication of advanced integrated circuits, such as CPUs, storage devices, ASICs (application specific integrated circuits) and the like, requires a large number of circuit elements, such as transistors, capacitors, resistors, etc., to be formed on a given chip area according to a specified circuit layout. During the fabrication of complex integrated circuits using, for instance, MOS (Metal-Oxide-Semiconductor) technology, millions of transistors, e.g., N-channel transistors (NFETs) and/or P-channel transistors (PFETs), are formed on a substrate including a crystalline semiconductor layer. A field effect transistor, irrespective of whether an NFET transistor or a PFET transistor is considered, typically includes doped source and drain regions that are formed in a semiconducting substrate and separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

In modern ultra-high density integrated circuits, the physical size of transistors have been steadily decreased in the past decades to enhance the performance of the semiconductor device and the overall functionality of the circuit. For example, the gate length (the distance between the source and drain regions) on modern transistor devices has been continuously reduced over the years and further scaling (reduction in size) is anticipated in the future. This ongoing and continuing decrease in the channel length of transistor devices has improved the operating speed of the transistors and integrated circuits that are formed using such transistors. However, there are certain problems that arise with the ongoing shrinkage of feature sizes that may at least partially offset the advantages obtained by such feature size reduction. For example, as the channel length is decreased, the pitch between adjacent transistors likewise decreases, thereby increasing the density of transistors per unit area. This scaling also limits the size of the conductive contact elements and structures that are formed to provide a means of electrical connection to the transistor, which has the effect of increasing their electrical resistance. In general, the reduction in feature size and increased packing density makes everything more crowded on modern integrated circuit devices, at both the device level and within the various metallization layers formed above the device level.

Typically, due to the large number of circuit elements and the required complex layout of modern integrated circuits, the electrical connections of the individual circuit elements cannot be established within the same level on which the circuit elements, such as transistors, are manufactured. Rather, modern integrated circuit products have multiple so-called metallization layer levels that, collectively, contain the “wiring” pattern for the product, i.e., the conductive structures that provide electrical connection to the transistors and the circuits, such as conductive metal vias and conductive metal lines. In general, the conductive metal lines are used to provide intra-level (same level) electrical connections, while inter-level (between levels) connections are vertical connections, which are also referred to as vias. In short, the vertically oriented conductive via structures provide the electrical connection between the various stacked metallization layers. Accordingly, the electrical resistance of such conductive structures, e.g., lines and vias, becomes a significant issue in the overall design of an integrated circuit product, since the cross-sectional area of these elements is correspondingly decreased, which may have a significant influence on the effective electrical resistance and overall performance of the final product or circuit.

Improving the functionality and performance capability of various metallization systems has also become an important aspect of designing modern semiconductor devices. One example of such improvements is reflected in the increased use of copper metallization systems in integrated circuit devices and the use of so-called “low-k” dielectric materials (materials having a dielectric constant less than about 3) in such devices. Copper metallization systems exhibit improved electrical conductivity as compared to, for example, prior metallization systems that used tungsten for the conductive lines and vias. The use of low-k dielectric materials tends to improve the signal-to-noise ratio (S/N ratio) by reducing crosstalk as compared to other dielectric materials with higher dielectric constants. However, the use of such low-k dielectric materials can be problematic as they tend to be less resistant to undesirable metal migration as compared to some other previously-used dielectric materials.

Copper is a material that is difficult to directly etch using traditional masking and etching techniques. Thus, conductive copper structures, e.g., conductive lines or vias, in modern integrated circuit devices are typically formed using known single or dual damascene techniques. In general, the damascene technique involves (1) forming a trench/via in a layer of insulating material, (2) depositing one or more relatively thin barrier or liner layers (e.g., TiN, Ta, TaN), (3) forming a copper seed layer above the barrier layers, (4) performing a bulk copper deposition process to form bulk copper material across the substrate and in the trench/via, and (5) performing at least one chemical mechanical polishing (CMP) process to remove the excess portions of the various materials positioned outside of the trench/via to define the final conductive copper structure. The copper material is typically formed by performing an electrochemical copper deposition process after a thin conductive copper seed layer is deposited by physical vapor deposition on the barrier layer.

FIG. 1 depicts an illustrative example of a representative prior art conductive copper structure 10, e.g., a conductive copper line. The copper structure 10 is positioned in a trench 14 that was formed in a layer of insulating material 11 by performing known photolithography and etching techniques. A polish-stop layer 12 is positioned above the layer of insulating material 11. As noted above, in this example, a first barrier layer 16 and a second barrier layer 18 are positioned in the trench 14. In one illustrative example, the first barrier layer 16 may be a layer of tantalum nitride (TaN) while the second barrier layer 18 may be a layer of tantalum (Ta). The barrier layers 16, 18 may be formed using a physical vapor deposition (PVD) process. The thickness of the barrier layers 16, 18 may vary depending upon the particular application, e.g., 0.5-3 nm. Also depicted in FIG. 1 is an illustrative copper-based seed layer 20. In more recent device generations, the copper-based seed layer 20 is typically a copper alloy, e.g., copper-aluminum or copper-manganese. The thickness of the copper seed layer 20 may vary depending upon the particular application, e.g., 40-50 nm. Lastly, the copper line 10 includes a region of bulk copper material 22. In the depicted example, the copper seed layer 20 is depicted as being still viewable as a discrete layer, but in a real-world device, all or most of the seed layer 20 would effectively be merged into and become part of the bulk copper material 22. The relative sizes of the layers 16, 18, and the region 22 may be exaggerated in FIG. 1 to facilitate explanation. A similar arrangement of layers and materials would be employed in forming a conductive via in the layer of insulating material 11.

While the above-described configuration of the copper line 10 and similarly constructed copper-based lines/vias has proven useful over the years, it is becoming more difficult to satisfy the ongoing demand for smaller and smaller conductive lines and conductive vias using such a process flow and the traditional materials for barrier layers and the copper seed layer. For example, the alloying elements aluminum and manganese are typically included as part of the copper-based seed layer 20, i.e., a copper-alloy seed layer, to increase the overall reliability of the conductive structure. More specifically, aluminum and manganese are added to the copper seed layer in an attempt to reduce undesirable electromigration which can degrade the performance capability of the conductive structure 10. As the overall size of the conductive structure 10 is reduced due to device scaling, it is even more important to insure that such alloying elements are provided in sufficient quantity or concentration to reduce the negative impact of electromigration on the smaller conductive structures 10. Unfortunately, such alloying elements are less electrically conductive than pure copper. As a result, using copper-based seed layers that include such alloying elements tends to increase the overall resistance of the conductive structure 10 due to the inclusion of such alloying materials in the copper seed layer. Lastly, the sheer reduction in the physical size of the conductive structure 10 due to device scaling means that there is physically less room in the trench 14 for all of the layers of material that are typically formed when forming such a conductive structure 10. The barrier layers 16, 18 as well as the copper-alloy seed layer 20 are all typically less electrically conductive than the bulk copper material 22. However, since that bulk copper material 22 is typically not formed in the trench 14 until after the other layers, e.g., the barrier layers 16, 18 and the copper-alloy seed layer 20, are formed, the volume of the trench occupied by the more conductive bulk copper material 22 is decreasing relative to the volume of the less electrically conductive materials 16, 18, and 20. Accordingly, the overall electrical resistance of the conductive structure 10 is increasing as device scaling continues.

The present disclosure is directed to various methods of forming barrier layers for copper-based conductive structures that may solve or at least reduce some of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming manganese-containing barrier layers for copper-based conductive structures, such as conductive lines/vias, that are formed on integrated circuit products. One illustrative method disclosed herein includes forming a trench/via in a layer of insulating material, forming a barrier layer in at least the trench/via, after forming said barrier layer, performing at least one process operation to introduce manganese into said barrier layer and thereby define a manganese-containing barrier layer, forming a substantially pure copper-based seed layer above the manganese-containing barrier layer, depositing a bulk copper-based material above the substantially pure copper-based seed layer so as to overfill the trench/via, and removing excess materials positioned outside of the trench/via to thereby define a copper-based conductive structure.

Another illustrative method disclosed herein includes forming a trench/via in a layer of insulating material, forming a barrier layer in at least the trench/via, wherein the barrier layer is comprised of at least one of the following materials: tantalum (Ta), niobium (Nb), Tungsten (W), vanadium (V), hafnium (Hf), titanium (Ti) and zirconium (Zr), after forming the barrier layer, performing one of a plasma doping process operation or at least one ion implantation process to introduce manganese into the barrier layer and thereby define a manganese-containing barrier layer, forming a substantially pure copper-based seed layer above the manganese-containing barrier layer, depositing a bulk copper-based material above the substantially pure copper-based seed layer so as to overfill the trench/via, and removing excess materials positioned outside of the trench/via to thereby define a copper-based conductive structure.

Yet another illustrative method disclosed herein includes forming a trench/via in a layer of insulating material, forming a barrier layer in at least the trench/via, after forming the barrier layer, performing a vertically oriented ion implantation process and a plurality of angled ion implantation processes to introduce manganese into the barrier layer and thereby define a manganese-containing barrier layer, forming a substantially pure copper-based seed layer on the manganese-containing barrier layer, depositing a bulk copper-based material above the substantially pure copper-based seed layer so as to overfill the trench/via, and removing excess materials positioned outside of the trench/via to thereby define a copper-based conductive structure.

Yet another illustrative method disclosed herein includes forming a trench/via in a layer of insulating material, forming a first barrier layer in at least the trench/via, wherein the first barrier layer is comprised of a first material combination that includes at least one of the following Group Y materials: tantalum (Ta), niobium (Nb), Tungsten (W), vanadium (V), hafnium (Hf), titanium (Ti) and zirconium (Zr), and at least one of the following Group X materials: titanium (Ti), cobalt (Co), ruthenium (Ru), manganese (Mn), aluminum (Al), nickel (Ni), chromium (Cr) and molybdenum (Mo), after forming the first barrier layer, forming a second barrier layer above the first barrier layer, wherein the second barrier layer is comprised of a second material combination that includes at least one of the Group Y materials and at least one of the Group X materials, and wherein the second material combination may be different from that of the first material combination, forming a substantially pure copper-based seed layer above the second barrier layer, depositing a bulk copper-based material above the substantially pure copper-based seed layer so as to overfill the trench/via, and removing excess materials positioned outside of the trench/via to thereby define a copper-based conductive structure.

### BRIEF DESCRIPTION OF THE DRAWINGS

The disclosure may be understood by reference to the following description taken in conjunction with the accompanying drawings, in which like reference numerals identify like elements, and in which:

FIG. 1 depicts an illustrative example of a prior art conductive structure formed using traditional techniques; and

FIGS. 2A-2Q depict various novel methods disclosed herein of forming barrier layers for copper-based conductive structures.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various novel methods of forming barrier layers for copper-based conductive structures, such as conductive lines/vias, that are formed on integrated circuit products. As will be readily apparent to those skilled in the art upon a complete reading of the present application, the present method is applicable to a variety of technologies, e.g., NFET, PFET, CMOS, etc., and is readily applicable to a variety of devices, including, but not limited to, ASIC's, logic devices, memory devices, etc. With reference to the attached drawings, various illustrative embodiments of the methods disclosed herein will now be described in more detail.

In general, prior art methods and structures for forming copper-based conductive structures sometimes focused on adding various alloying elements, such as aluminum and manganese, to the copper-based seed layer in an attempt to prevent or reduce, among other thing, undesirable electromigration of the final conductive copper structure. The novel methods and structures disclosed herein involve techniques, materials and structures wherein the barrier layer(s) are made of material that may eliminate or reduce the requirement of including such alloying materials in the copper seed layer. In general, one or more barrier layers disclosed herein are made of a combination of materials. In one example, the barrier layers disclosed herein may be comprised of at least one material selected from the below-identified “Group Y” materials and at least one material selected from the below-identified “Group X” materials. In the numbering sequence employed herein, the subscript “Y”, e.g., 108_{Y} indicates that the given material layer includes at least one material selected from the below-identified “Group Y” materials, while the suffix “A_{X}”, e.g., 108_{Y}A_{X} indicates that the given material layer is an alloy (“A”) that includes at least one material selected from the below-identified “Group X” materials. The relative amount of the material from Groups X and Y in any particular barrier layer disclosed herein may vary depending upon the particular application. In general, the combined amount or concentration of the Group Y materials will total at least about 2% of the Group X materials in the final barrier layer. In some cases, the combined amount or concentration of the Group X and Y materials will approach or equal about 100% in the final barrier layer.

FIG. 2A is a simplified view of an illustrative integrated circuit device 100 at an early stage of manufacturing that is formed above a semiconductor substrate (not shown). The device 100 may be any type of integrated circuit device that employs any type of a conductive copper structure, such as a conductive line or via, commonly found on integrated circuit devices. At the point of fabrication depicted in FIG. 2A, an illustrative trench/via 104 has been formed in a layer of insulating material 102 by performing known photolithography and etching techniques through a patterned mask layer 106. The trench/via 104 is intended to be representative of any type of opening, recess or trench formed in any type of insulating material 102 wherein a conductive copper structure may be formed. The trench/via 104 may be of any desired shape, depth or configuration. For example, in some embodiments, the trench/via 104 is a classic trench that does not extend to an underlying layer of material, such as the illustrative trench 104 depicted in FIG. 2A. In other embodiments, the trench/via 104 may be a through-hole type feature, e.g., a classic via, that extends all of the way through the layer of insulating material 102 and exposes an underlying layer of material or an underlying conductive structure (not shown), such as an underlying metal line. Thus, the shape, size, depth or configuration of the trench/via 104 should not be considered to be a limitation of the present invention. The trench/via 104 may be formed by performing any of a variety of different etching processes, e.g., a dry reactive ion etching process, through the illustrative patterned mask layer 106. With continuing reference to FIG. 2A, illustrative barrier layers 108_{Y}A_{X} and 110_{Y}A_{X}, a copper-based seed layer 112 and a bulk-deposited layer of bulk copper 114 have been deposited above the device 100 and in the trench/via 104.

FIG. 2B depicts the product 100 after one or more planarization processes, such as chemical mechanical polishing (CMP) processes, have been performed on the product 100 to remove excess materials positioned outside of the trench/via 104 and thereby define one illustrative embodiment of a copper-based conductive structure 105 that employs one or more of the novel barrier layer structures disclosed herein. In one example, one or more of the CMP processes stops on the layer 106. In the depicted example, two illustrative barrier layers disclosed herein (108_{Y}A_{X}, 110_{Y}A_{X}) are employed in forming the illustrative copper-based conductive structure 105. However, as will be recognized by those skilled in the art after a complete reading of the present application, the conductive copper structures disclosed herein may be formed using one or more of the novel barrier layers disclosed herein, e.g., in FIGS. 2A-2B, the barrier layer 110_{Y}A_{X} could have been omitted. In addition, as described more fully below, the products 100 disclosed herein may additionally include one or more barrier layers made of traditional barrier layer materials. In one embodiment, the barrier layers 108_{Y}A_{X}, 110_{Y}A_{X} may be comprised of different combinations of the Group Y and Group X materials. For example, the barrier layer 108_{Y}A_{X} may be comprised of tantalum-cobalt, while the barrier layer 110_{Y}A_{X} may be comprised of tantalum-titanium. As another example, the barrier layer 108_{Y}A_{X} may be comprised of tungsten-aluminum, while the barrier layer 110_{Y}A_{X} may be comprised of niobium-manganese.

In one particularly illustrative example, by including various alloy elements in one or more of the barrier layers 108_{Y}A_{X}, 110_{Y}A_{X}, the seed layer 112 may be made of substantially pure copper, i.e., the alloying elements typically found in prior art copper seed layers, such as aluminum and manganese, are not present in the substantially pure copper seed layer 112 disclosed herein. As used herein and in the claims, “substantially pure copper” means copper material that is deposited from a non-alloyed target with typical compositions that are known to those skilled in the art or a copper material exhibiting a degree of purity of at least 99%.

The various components and layers of the device 100 may be initially formed using a variety of different materials and by performing a variety of known techniques. For example, the layer of insulating material 102 may be comprised of any type of insulating material, e.g., silicon dioxide, a low-k insulating material (k value less than 3), etc., it may be formed to any desired thickness and it may be formed by performing, for example, a chemical vapor deposition (CVD) process or spin-on deposition (SOD) process, etc. The patterned mask layer 106 used in forming the trench/via 104 may be formed using known photolithography and/or etching techniques. The patterned mask layer 106 is intended to be representative in nature as it could be comprised of a variety of materials, such as, for example, a photoresist material, silicon nitride, silicon oxynitride, silicon dioxide, a metal, etc. Moreover, the patterned mask layer 106 could be comprised of multiple layers of material, such as, for example, a pad oxide layer (not shown) and a pad silicon nitride layer (not shown) that is formed on the pad oxide layer. Thus, the particular form and composition of the patterned mask layer 106 and the manner in which it is made should not be considered a limitation of the present invention. In the case where the patterned mask layer 106 is comprised of one or more hard mask layers, such layers may be formed by performing a variety of known processing techniques, such as a CVD process, an atomic layer deposition (ALD) process, a physical vapor deposition (PVD) process, or plasma enhanced versions of such processes, and the thickness of such a layer(s) may vary depending upon the particular application. In one illustrative embodiment, the patterned mask layer 106 is a hard mask layer of silicon nitride that is initially formed by performing a CVD process to deposit a layer of silicon nitride and thereafter patterning the layer of silicon nitride using known sidewall image transfer techniques and/or photolithographic techniques combined with performing known etching techniques.

FIGS. 2C-2D depict an illustrative example wherein a single barrier layer 116_{Y}A_{X} is formed as part of the process of forming another illustrative embodiment of the conductive structure 105. FIG. 2D depicts the product 100 after one or more CMP processes have been performed. In this particular example, the materials “X” and “Y” may be introduced into the barrier layer 116_{Y}A_{X} as it is being formed. Alternatively, the barrier layer 116_{Y}A_{X} may simply be a thicker version of one or more of the barrier layers 108_{Y}A_{X}, 110_{Y}A_{X}, described above. One particular manner in which the barrier layer 116_{Y}A_{X} may be formed will be discussed more fully below.

The thickness of the barrier layers disclosed herein may vary depending upon the particular application. In one illustrative embodiment, the thickness of each of the barrier layers 108_{Y}A_{X}, 110_{Y}A_{X} may be about 0.5-3 nm. In connection with the formation of the barrier layers disclosed herein, the Group Y materials include tantalum (Ta), niobium (Nb), Tungsten (W), vanadium (V), hafnium (Hf), titanium (Ti), or zirconium (Zr), as well as nitrides, borides or phosphides made of such materials. The Group X materials referenced herein include titanium (Ti), cobalt (Co), ruthenium (Ru), manganese (Mn), aluminum (Al), nickel (Ni), chromium (Cr) and molybdenum (Mo), as well as nitrides, carbides, carbonitrides, borides or phosphides made of such materials.

FIGS. 2E-2H will be referenced to describe one illustrative embodiment of the various methods disclosed herein, wherein the above described “X” and “Y” numbering designation and cross-hatch shading of the barrier layers will be employed to facilitate a clear understanding of the methods disclosed herein. To that end, FIG. 2E depicts the product at a point of fabrication wherein a conformal deposition process is performed to form an initial layer of barrier material 108_{Y}. In this example, the barrier layer does not include any of the Group X elements described above, as reflected by the lack of any cross-sectional shading of the layer of barrier material 108_{Y}. The layer of barrier material 108_{Y} may be formed using any traditional process operation, e.g., CVD, PVD, ALD, or plasma enhanced versions of such process operations.

Next, as shown in FIG. 2F, one or more process operations 120 are performed on the product 100 to introduce one or more of the Group X materials into the layer of barrier material 108_{Y}, to thereby result in the formation of the barrier layer 108_{Y}A_{X}, as reflected by the new reference number and the additional cross-hatching of the layer, i.e., compare FIG. 2E with FIG. 2F. In one illustrative embodiment, the process operation 120 may be a plasma doping process that is performed to introduce at least one of the Group X materials disclosed above into the layer of barrier material 108_{Y} shown in FIG. 2E. In another illustrative example, the process operation 120 may be a sequence of ion implantation processes that are performed to introduce at least one of the Group X materials disclosed above into the layer of barrier material 108_{Y} shown in FIG. 2E. To insure uniform introduction of the material(s) from the Group X material into the barrier layer 108_{Y} that is formed in the trench/via 104, one illustrative embodiment of such an ion implantation process sequence may include a vertically oriented ion implantation process as well as four additional angled ion implantation processes, wherein the product 100 is rotated about 90 degrees for each of the angled implantation processes. In the case where the process operation 120 includes at least one ion implantation process, the implant dose and the implant energy may vary depending upon the particular application. In one illustrative embodiment, the implant dose of the Group X material may be about 10e¹⁴-10e¹⁷ ions/cm², and it may be performed using an implant energy level of about 0.2-20 keV.

FIGS. 2G-2H will be referenced to describe one illustrative embodiment of a method of forming the illustrative barrier layer 110_{Y}A_{X} depicted above. To that end, FIG. 2G depicts the product 100 at a point of fabrication wherein a conformal deposition process was performed to form an initial layer of barrier material 110_{Y} above the previously formed barrier 108_{Y}A_{X}. The layer 110_{Y} does not include any of the Group X elements described above, as reflected by the lack of any cross-sectional shading of the layer of barrier material 110_{Y}. The layer of barrier material 110_{Y} may be formed using any traditional process operation, e.g., CVD, PVD, ALD, or plasma enhanced versions of such process operations.

Next, as shown in FIG. 2H, one or more process operations 122 are performed on the product 100 to introduce one or more of the Group X materials into the layer of barrier material 110_{Y}, to thereby result in the formation of the barrier layer 110_{Y}A_{X}, as reflected by the new reference number and the additional cross-hatching of the layer, i.e., compare FIG. 2G with FIG. 2H. In one illustrative embodiment, the process operation 122 may be the same as the process operation 120 described above. In general, the process operation 122 may be a plasma doping process that is performed to introduce at least one of the Group X materials disclosed above into the layer of barrier material 110_{Y} shown in FIG. 2G. In another illustrative example, the process operation 122 may be a sequence of ion implantation processes that are performed to introduce least one of the Group X materials disclosed above into the layer of barrier material 110_{Y} shown in FIG. 2G. To insure uniform introduction of the material(s) from the Group X material into the barrier layer 110_{Y} that is formed in the trench/via 104, one illustrative embodiment of such an ion implantation process sequence may include a vertically oriented ion implantation process as well as four additional angled ion implantation processes, wherein the product 100 is rotated about 90 degrees for each of the angled implantation processes. In the case where the process operation 122 includes at least one ion implantation process, the implant dose and the implant energy may vary depending upon the particular application. In one illustrative embodiment, the implant dose of the Group X material may be about 10e¹⁴-10e¹⁷ ions/cm², and it may be performed using an implant energy level of about 0.2-20 keV.

As mentioned above, the novel barrier layers disclosed herein may be employed with one or more traditional barrier layer materials if desired or warranted by the particular application. FIG. 2I depicts an illustrative example where the novel barrier layer 108_{Y}A_{X} disclosed herein is employed with a traditional barrier layer 130 comprised of a traditional barrier material such as, for example, tantalum, cobalt, ruthenium, manganese, tantalum nitride, titanium nitride, tungsten nitride, titanium or combinations thereof. The thickness of the barrier layer 130 may vary depending upon the particular application, e.g., 0.5-3 nm. The barrier layer 130 may be formed any of a variety of known techniques, e.g., PVD, CVD, ALD, etc. In this depicted example, the traditional barrier layer 130 is formed above the barrier layer 108_{Y}A_{X}. Thereafter, the copper seed layer 112 and bulk copper material 114 are formed using traditional techniques. FIG. 2J depicts the product 100 after one or more planarization processes, such as chemical mechanical polishing (CMP) processes, have been performed on the product 100 to remove excess materials positioned outside of the trench/via 104 and thereby define one illustrative embodiment of a copper-based conductive structure 105 that employs the novel barrier layer 108_{Y}A_{X} and the traditional barrier layer 130.

FIGS. 2K-2L depict an illustrative example wherein the traditional barrier layer 130 is formed prior to the formation of the barrier layer 110_{Y}A_{X}. Thereafter, the barrier layer 110_{Y}A_{X}, the copper seed layer 112 and bulk copper material 114 are formed above the traditional barrier layer 130. FIG. 2L depicts the product 100 after one or more planarization processes, such as chemical mechanical polishing (CMP) processes, have been performed on the product 100 to remove excess materials positioned outside of the trench/via 104 and thereby define one illustrative embodiment of a copper-based conductive structure 105 that employs the novel barrier layer 110_{Y}A_{X} and a traditional barrier layer 130.

FIG. 2M depicts an illustrative example of where a novel barrier layer disclosed herein may be formed in a deposition process 124 wherein materials from Group Y and Group X are introduced as the barrier layer is being formed. In one example, the process 124 may be a CVD, ALD, or PVD process during which one or more materials selected from Group Y and one or more materials selected form Group X are present or introduced when the illustrative barrier layer 116_{Y}A_{X} is formed in and above the trench/via 194. For example, the process operation 124 may be a PVD process that employs a single target comprised of the selected materials from Groups Y and X. Alternatively, the process operation 124 may be a PVD process that employs two separate targets (a co-sputtering process), wherein one of the targets contains at least the material from Group Y and the other target includes the material from Group X. In the case where the process operation 124 is a CVD process, the appropriate precursors may be introduced during the CVD process. At the point of fabrication depicted in FIG. 2M, an additional novel barrier layer disclosed herein, a traditional barrier layer 130 and/or the copper seed layer 112 may be formed above the barrier layer 116_{Y}A_{X}. Thereafter, bulk copper material 114 may be formed in the trench/via 104 and a CMP process may be performed to remove the excess materials positioned outside of the trench/via 104.

FIGS. 2N-2O depict an illustrative example wherein an illustrative layer of silicon 140 is formed between one or more of the novel barrier layers disclosed herein and the copper seed layer 112. The thickness of the layer of silicon 140 may vary depending upon the particular application, e.g., 0.5-3 nm. The layer of silicon 140 may be formed by any of a variety of known techniques, e.g., PVD, CVD, ALD, etc. In the depicted example, the layer of silicon 140 is formed above the barrier layer 110_{Y}A_{X}. Thereafter, the copper seed layer 112 and bulk copper material 114 are formed using traditional techniques. FIG. 2O depicts the product 100 after one or more planarization processes, such as chemical mechanical polishing (CMP) processes, have been performed on the product 100 to remove excess materials positioned outside of the trench/via 104 and thereby define one illustrative embodiment of a copper-based conductive structure 105 that employs the novel barrier layers 108_{Y}A_{X}, 110_{Y}A_{X} and the layer of silicon 140.

FIGS. 2P-2Q depict an illustrative example wherein the illustrative layer of silicon 140 is formed between the novel barrier layer 116_{Y}A_{X} and the copper seed layer 112.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a trench/via in a layer of insulating material;
forming a barrier layer in at least said trench/via;
after forming said barrier layer, performing at least one process operation to introduce manganese into said barrier layer and thereby define a manganese-containing barrier layer;
forming a substantially pure copper-based seed layer above said manganese-containing barrier layer;
depositing a bulk copper-based material above said substantially pure copper-based seed layer so as to overfill said trench/via; and
removing excess materials positioned outside of said trench/via to thereby define a copper-based conductive structure.

2. The method of claim 1, wherein performing said at least one process operation comprises performing one of a plasma doping process operation or at least one ion implantation process.

3. The method of claim 2, wherein performing said at least one ion implantation process comprises performing a vertically oriented ion implantation process and a plurality of angled ion implantation processes.

4. The method of claim 1, wherein said barrier layer is comprised of at least one of the following materials: tantalum (Ta), niobium (Nb), Tungsten (W), vanadium (V), hafnium (Hf), titanium (Ti) and zirconium (Zr).

5. The method of claim 1, wherein said copper-based seed layer is free of manganese.

6. The method of claim 1, wherein said copper-based conductive structure is one of a conductive line or a conductive via.

7. The method of claim 1, further comprising forming a traditional barrier layer adjacent one of said layer of insulating material or said manganese-containing barrier layer, wherein said traditional barrier layer is comprised of tantalum, cobalt, ruthenium, manganese, tantalum nitride, titanium nitride, titanium or any combination of such materials, or carbides, carbonitrides, borides or phosphides of such materials.

8. The method of claim 1, wherein said substantially pure copper seed layer is formed on said manganese-containing barrier layer.

9. A method, comprising:
forming a trench/via in a layer of insulating material;
forming a barrier layer in at least said trench/via, said barrier layer being comprised of at least one of the following materials: tantalum (Ta), niobium (Nb), Tungsten (W), vanadium (V), hafnium (Hf), titanium (Ti) and zirconium (Zr);
after forming said barrier layer, performing one of a plasma doping process operation or at least one ion implantation process to introduce manganese into said barrier layer and thereby define a manganese-containing barrier layer;
forming a substantially pure copper-based seed layer above said manganese-containing barrier layer;
depositing a bulk copper-based material above said substantially pure copper-based seed layer so as to overfill said trench/via; and
removing excess materials positioned outside of said trench/via to thereby define a copper-based conductive structure.

10. The method of claim 9, wherein performing said at least one ion implantation process comprises performing a vertically oriented ion implantation process and a plurality of angled ion implantation processes.

11. The method of claim 9, further comprising forming a traditional barrier layer adjacent one of said layer of insulating material or said manganese-containing barrier layer, wherein said traditional barrier layer is comprised of tantalum, cobalt, ruthenium, manganese, tantalum nitride, titanium nitride, titanium or any combination of such materials, or carbides, carbonitrides, borides or phosphides of such materials.

12. The method of claim 9, wherein said substantially pure copper seed layer is formed on said manganese-containing barrier layer.

13. A method, comprising:
forming a trench/via in a layer of insulating material;
forming a barrier layer in at least said trench/via;
after forming said barrier layer, performing a vertically oriented ion implantation process and a plurality of angled ion implantation processes to introduce manganese into said barrier layer and thereby define a manganese-containing barrier layer;
forming a substantially pure copper-based seed layer on said manganese-containing barrier layer;
depositing a bulk copper-based material above said substantially pure copper-based seed layer so as to overfill said trench/via; and
removing excess materials positioned outside of said trench/via to thereby define a copper-based conductive structure.

14. The method of claim 13, wherein said barrier layer is comprised of at least one of the following materials: tantalum (Ta), niobium (Nb), Tungsten (W), vanadium (V), hafnium (Hf), titanium (Ti) and zirconium (Zr).

15. A method, comprising:
forming a trench/via in a layer of insulating material;
forming a first barrier layer in at least said trench/via, said first barrier layer being comprised of a first material combination that includes at least one of the following Group Y materials: tantalum (Ta), niobium (Nb), Tungsten (W), vanadium (V), hafnium (Hf), titanium (Ti) and zirconium (Zr), and at least one of the following Group X materials: titanium (Ti), cobalt (Co), ruthenium (Ru), manganese (Mn), aluminum (Al), nickel (Ni), chromium (Cr) and molybdenum (Mo);
after forming said first barrier layer, forming a second barrier layer above said first barrier layer, said second barrier layer being comprised of a second material combination that includes at least one of the Group Y materials and at least one of the Group X materials, wherein said second material combination is different from that of said first material combination;
forming a substantially pure copper-based seed layer above said second barrier layer;
depositing a bulk copper-based material above said copper-based seed layer so as to overfill said trench/via; and
removing excess materials positioned outside of said trench/via to thereby define a copper-based conductive structure.

16. The method of claim 15, wherein said first barrier layer is comprised of a carbide, carbonitride, boride or phosphide of any of said Group Y materials.
